(19) United States
(12) Patent Application Publication
(10) Pub. No.: US 2013/0285232 A1
(43) Pub. Date: Oct. 31, 2013

(54) SEMICONDUCTOR PACKAGE MODULE

(71) Applicant: Job Ha, Gyunggi-do (KR)

(72) Inventor: Job Ha, Gyunggi-do (KR)

(73) Assignee: SAMSUNG ELECTRO-MECHANICS CO., LTD., Gyunggi-do (KR)

(21) Appl. No.: 13/546,433

(22) Filed: Jul. 11, 2012

(30) Foreign Application Priority Data
Apr. 27, 2012 (KR) 1020120044568

(51) Int. Cl. H01L 23/48

(52) U.S. Cl. 257/696; 257/E23.01

(57) ABSTRACT

Disclosed herein is a semiconductor package module, including: a circuit board having connection pads formed on one surface thereof; a semiconductor package including lead terminals protruded out of a housing; and an interposer positioned between the circuit board and the semiconductor package, the interposer including a body allowing the circuit board and the semiconductor package to be spaced apart from each other and elastic members contacted with the connection pads and the lead terminals.

### CROSS REFERENCE TO RELATED APPLICATION

This application claims the benefit of Korean Patent Application No. 10-2012-0044568, filed on Apr. 27, 2012, entitled “Semiconductor Package Module”, which is hereby incorporated by reference in its entirety into this application.

### BACKGROUND OF THE INVENTION

1. Technical Field

The present invention relates to a semiconductor package module.

2. Description of the Related Art

A semiconductor package may be manufactured by loading one or more semiconductor chips on a lead frame or a printed circuit board and using a sealing resin or a housing to protect an inside thereof. This semiconductor package may be mounted on a circuit board such as a main board, a printed circuit board (PCB), a printed board assembly (PBA), or the like. In related are, the semiconductor package is combined with the circuit board by penetration-inserting external lead terminals of the semiconductor package into connection pads of the circuit board. Also, the semiconductor package is combined with the circuit board by soldering the external lead terminals of the semiconductor package to the connection pads of the circuit board. The prior art discloses that the semiconductor package and the circuit board are electrically connected to each other by combining the semiconductor package with the circuit board in the above manner (U.S. Pat. No. 4,980,753).

### SUMMARY OF THE INVENTION

The present invention has been made in an effort to provide a semiconductor package module capable of electrically connecting a semiconductor package and a circuit board in a non-soldering manner.

The present invention has been made in an effort to provide a semiconductor package module capable of preventing cracks from being generated by combining a semiconductor package and a circuit board in a non-soldering manner.

The present invention has been made in an effort to provide a semiconductor package module capable of improving durability against external physical impact by combining a semiconductor package and a circuit board in a non-soldering manner.

According to a preferred embodiment of the present invention, there is provided a semiconductor package module, including: a circuit board having connection pads formed on one surface thereof; a semiconductor package including lead terminals protruded out of a housing; and an interposer positioned between the circuit board and the semiconductor package, the interposer including a body allowing the circuit board and the semiconductor package to be spaced apart from each other and elastic members contacted with the connection pads and the lead terminals.

The body may include elastic member mounting parts for mounting the elastic members therein, respectively.

The elastic member mounting part may be in a penetration hole type penetrating through the body.

The elastic member mounting part may include an elastic member fixing portion fixing the elastic member.

The elastic member fixing portion may include one pair of first and second elastic member fixing elements protruded from both internal walls of the elastic member mounting part toward a center thereof.

The elastic member may include: a pad connection portion contacted with the connection pads of the circuit board; a lead insertion portion inserting the lead terminals of the semiconductor package thereinto; a fixing portion fixed to the elastic member fixing portion of the body.

The elastic member may be formed in an integral type.

The pad connection portion, the lead insertion portion, and the fixing portion of the elastic member may be bent toward one another and connected with one another.

The elastic member may include: a first lower fixing element fixed to a lower surface of the first elastic member fixing element formed on one internal wall of the elastic member mounting part; a first bending element bent from one side of the first lower fixing element to the inside upwardly; a second bending element bent from one side of the first bending element to the outside downwardly; a first upper fixing element bent from one side of the second bending element to the outside upwardly, and fixed to an upper surface of the first elastic member fixing element; a first pad connection element bent from one side of the first upper fixing element to the inside thereof; a second lower fixing element fixed to a lower surface of the second elastic member fixing element formed on the other internal wall of the elastic member mounting part; a third bending element bent from one side of the second lower fixing element to the inside upwardly; a fourth bending element bent from one side of the third bending element to the outside downwardly; a second upper fixing element bent from one side of the fourth bending element to the outside upwardly, and fixed to an upper surface of the second elastic member fixing element and a second pad connection element bent from one side of the second upper fixing element to the inside thereof, one side of the second upper fixing element being connected with one side of the first pad connection element.

In the elastic member, the lead terminal of the semiconductor package may be inserted and fixed between the second bending element and the fourth bending element.

The first pad connection element and the second pad connection element may be contacted with the connection pad of the circuit board.

The body may be formed of an insulating material, and the elastic member may be formed of a conductive material.

The semiconductor package module may further include at least one protrusion protruded from at least one of an upper surface and a lower surface of the body in a thickness direction of the body.

The semiconductor package may include at least one of a power device and a control device.

The semiconductor package may include: a first semiconductor package including a power device and the lead terminals protruded out of the housing; and a second semiconductor package including a control device and a control substrate electrically connected with the lead terminals.

The lead terminals may be penetration-inserted into the control substrate.

The control device may be inserted into the body of the interposer.

The semiconductor package module may further include a heat radiating unit formed below the semiconductor package.

The circuit board, the semiconductor package, the interposer, and the heat radiating unit may be fixed to one another by a coupling unit.

The coupling unit may be a bolt.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified view showing a semiconductor package module according to a preferred embodiment of the present invention;

FIG. 2 is an exemplified view showing a cross section of an interposer according to a preferred embodiment of the present invention;

FIG. 3 is an exemplified view showing an elastic member according to a preferred embodiment of the present invention;

FIG. 4 is an exemplified view showing an elastic member contacted with a lead terminal and a connection pad according to a preferred embodiment of the present invention;

FIG. 5 is an exemplified view showing a semiconductor package module according to another preferred embodiment of the present invention;

FIG. 6 is an exemplified view showing a semiconductor package module according to still another preferred embodiment of the present invention;

FIG. 7 is an exemplified view showing a semiconductor package module according to still another preferred embodiment of the present invention; and

FIG. 8 is an exemplified view showing a semiconductor package module according to still another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

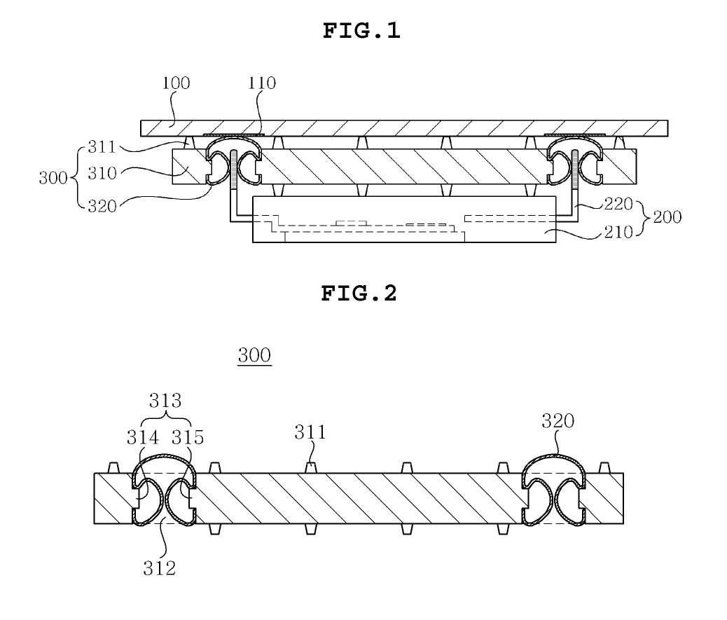

FIG. 1 is an exemplified view showing a semiconductor package module according to a preferred embodiment of the present invention.

Referring to FIG. 1, a semiconductor package module may include a circuit board 100, a semiconductor package 200, and an interposer 300.

The circuit board 100 may be a printed circuit board having a circuit layer formed thereon. Also, the circuit board 100 may have a structure in which a semiconductor chip is provided on a board having a circuit layer formed thereon. Here, the semiconductor chip may be electrically connected to the circuit layer. For example, the circuit board 100 may be a printed board assembly (PBA). Connection pads 110 may be formed on one surface of the circuit board 100. The connection pads 1100 may be electrically connected with the circuit layer or the semiconductor chip formed on the circuit board 100.

The semiconductor package 200 may be a power device or a control device. The semiconductor package 200 may have a structure where constituents such as the power device, the control device, the printed circuit board, and the like are positioned and packaged inside the housing 210. The power device and the control device may be electrically connected with the printed circuit board inside the semiconductor package 200 by wires or a lead frame.

The semiconductor package 200 may include lead terminals 220 protruded from an inside to an outside of the housing 210. The lead terminals 220 may electrically connect internal constituent parts and external constituent parts of the semiconductor package 200. For example, the internal constituent parts of the semiconductor package 200 may be electrically connected with the circuit board 100 or the elastic member 320 of the interposer 300 through the lead terminals 220.

The interposer 300 is one constituent part for electrically connecting the semiconductor package 200 and the circuit board 100 with each other. The interposer 300 may include a body 310 and elastic members 320. The body 310 may be formed of an insulating material. The body 310 may allow the semiconductor package 200 and the circuit board 100 to be spaced apart from each other at a predetermined spaced distance. The body 310 may have protrusions 311 formed on an upper surface and a lower surface thereof. The protrusions 311 may be protruded from the upper surface and the lower surface of the body 310 in a thickness direction thereof. The protrusions 311 may be also formed in order to maintain a spaced distance from the semiconductor package 200 or the circuit board 100. Here, one or more protrusions 311 may be formed.

The elastic members 320 may be mounted inside the body 310. In addition, the elastic members 320 may be formed of a conductive material. The elastic members 320 may be contacted with the lead terminals 220 of the semiconductor package 200. Also, the elastic members 320 may be contacted with the connection pads 110 of the circuit board 100. The elastic members 320 may be respectively contacted with the lead terminals 220 and the connection pads 110, to thereby electrically connect the lead terminals 220 and the connection pads 110 with each other. That is, the semiconductor package 200 and the circuit board 100 may be electrically connected with each other by the elastic members 320.

In the semiconductor package module according to the preferred embodiment of the present invention, the semiconductor package 200 and the circuit board 100 may be connected with each other by the interposer 300 in a non-soldering manner. That is, the lead terminals 220 of the semiconductor package 200 and the connection pads 110 of the circuit board 100 may be respectively contacted with the elastic members 320 of a conductive material, to thereby achieve electric connection therebetween. As such, thermal damage of the semiconductor package 200 and the circuit board 100 due to soldering may be prevented by the interposer 300. In addition, the interposer 300 can prevent the generation of cracks, which is caused by a difference in coefficient of thermal expansion between the semiconductor package 200 and the circuit board 100 in a conventional soldering manner. In addition, the interposer 300 are respectively contacted with the semiconductor package 200 and the circuit board 100, to thereby achieve electric connection therebetween, and thus, the interposer 300 can reduce defects in electric connection between the semiconductor package 200 and the circuit board 100 due to external impact.

FIG. 2 is an exemplified view showing a cross section of the interposer 300 according to the preferred embodiment of the present invention.

The interposer 300 is one constituent part for electrically connecting the semiconductor package 200 and the circuit board 100 with each other.

Referring to FIG. 2, the interposer 300 may include a body 310 and elastic members 320. The body 310 may allow the semiconductor package 200 and the circuit board 100 to be spaced apart from each other at a predetermined spaced distance. The body 310 may include elastic member mounting parts 312 in which the elastic members 320 are mounted. The elastic member mounting part 312 may be formed in a penetration hole type penetrating through the body 310. The elastic member 320 may be inserted and mounted in the penetration hole type elastic member mounting part 312. The elastic member mounting part 312 may include elastic member fixing portion 313 for fixing the inserted elastic member 320. The elastic member fixing portion 313 may be formed in one pair that is protruded from both internal walls of the elastic member mounting part 312 toward the center thereof. For example, the elastic member fixing portion 313 may include a first elastic member fixing element 314 formed on one internal wall of the elastic member mounting part 312. Also, the elastic member fixing portion 313 may include a second elastic member fixing element 315 formed on the other internal wall of the elastic member mounting part 312. Here, the first elastic member fixing element 314 and the second elastic member fixing element 315 may be formed oppositely to each other. The first elastic member fixing element 314 is inserted into a portion of one inside of the elastic member 320, so that one side of the elastic member 320 and the first elastic member fixing element 314 may be mounted on and fixed to each other. Also, the second elastic member fixing element 315 is inserted into a portion of the other side of the elastic member 320, so that the other side of the elastic member 320 and the second elastic member fixing element 315 may be mounted on and fixed to each other.

The body 310 may have protrusions 311 formed on an upper surface and a lower surface thereof. The protrusions 311 may be protruded outwardly from the upper surface and the lower surface of the body 310. The protrusions 311 may be formed in order to maintain a spaced distance from the semiconductor package 200 or the circuit board 100. Here, one or more protrusions 311 may be formed.

The body 310 formed as above may be formed of an insulating material.

The body 310 may allow the semiconductor package 200 and the circuit board 100 to be spaced apart from each other at a predetermined spaced distance, and also allow the elastic member 320 to maintain a predetermined pressure. The predetermined pressure needs to be applied to both lateral surfaces of the elastic member 320, so that the lead terminal 220 of the semiconductor package 200 is inserted into and fixed to the elastic member 320. If the predetermined pressure is not applied to both lateral surfaces of the elastic member 320 by the body 310, the lead terminal 220 inserted into the elastic member 320 may be difficult to fix. Also, if the lead terminals 220 are not inserted into the elastic member 320, electric connection therebetween may be difficult. As such, the body 310 may allow the predetermined pressure to be applied to both lateral surfaces of the elastic member 320, and thus, the elastic member 320 can maintain reliable contact with the lead terminals 220 of the semiconductor package 200.

In addition, the elastic member 320 can maintain a predetermined height thereof, by allowing the body 310 to apply the predetermined pressure to both lateral surfaces of the elastic member 320. If the predetermined pressure is not applied to both lateral surfaces of the elastic member 320 by the body 310, the elastic member 320 can not maintain a predetermined height, due to pressure generated above and below at the time of screw coupling of the semiconductor package module later. In the case where the elastic member 320 has difficulty in maintaining a predetermined height, reliable connection between the elastic member 320 and the connection pads 110 of the circuit board 100 positioned above the elastic member 320. As such, the elastic member 320 maintains a predetermined height thereof by the body 310, and thus, the elastic member 320 can maintain reliable contact with the connect pads 110 of the circuit board 100.

The elastic member 320 may be inserted into and fixed to the elastic member mounting part 312 of the body 310. The elastic member 320 may electrically connect the circuit board 100 and the semiconductor package 200 with each other. That is, the elastic members 320 may be contacted with the lead terminals 220 of the semiconductor package 200, which are inserted into a lower portion of the elastic member mounting part 312. In addition, the elastic members 320 may be contacted with the connection pads 110 of the circuit board 100 positioned above the elastic member mounting part 312. As such, the lead terminals 220 and the connection pads 110 are respectively contacted with the elastic member 320, so that the semiconductor package 200 and the circuit board 100 can be electrically connected with each other. The elastic members 320 may be formed of a conductive material. In addition, the elastic member 320 may be formed of an elastic material.

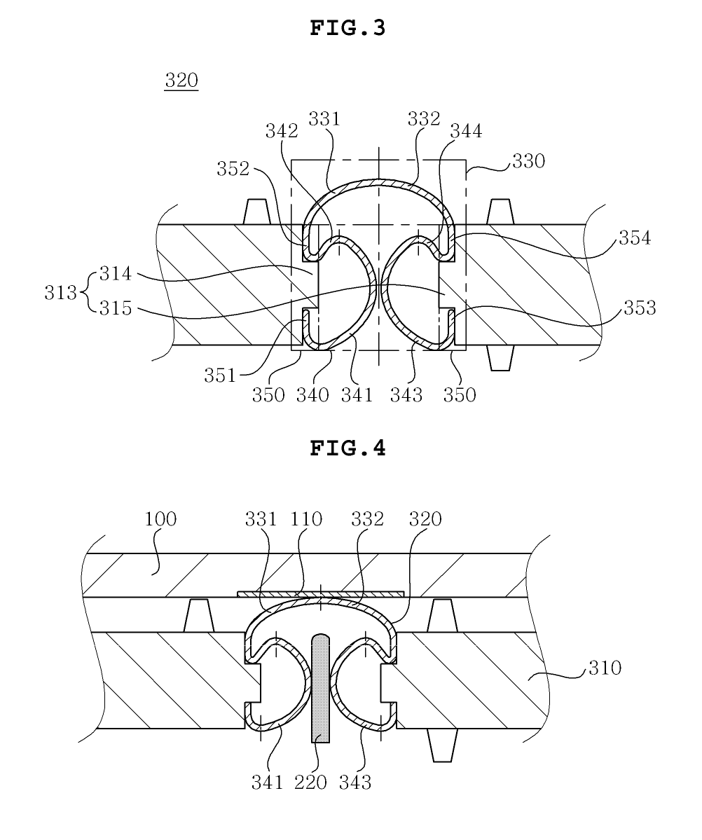

FIG. 3 is an exemplified view showing an elastic member according to a preferred embodiment of the present invention.

Referring to FIG. 3, the elastic member 320 may include a pad connection portion 330, a lead insertion portion 340, and a fixing portion 350 depending on the functions thereof.

The pad connection portion 330 may be contacted with the connection pads 110 of the circuit board 100.

The lead terminals 220 of the semiconductor package 200 may be inserted into the lead insertion portion 340.

The fixing portion 350 may be fixed to the elastic member fixing portion 313 of the body 310.

In addition, the elastic member 320 may be formed in an integral type. That is, the pad connection portion 330, the lead insertion portion 340, and the fixing portion 350 may be formed in an integral type. In addition, the pad connection portion 330, the lead insertion portion 340, and the fixing portion 350 may be formed in an integral type, and respectively bent and connected to each other.

The fixing portion 350 may include a first lower fixing element 351, a second lower fixing element 353, and a first upper fixing element 352, and a second upper fixing element 354.

In addition, the lead insertion portion 340 may include a first bending element 341, a second bending element 342, a third bending element 343, and a fourth bending element 344.

In addition, the pad connection portion 330 may include a pad connection element 331 and a second pad connection element 332.

The other side of the first lower fixing element 351 may be fixed to a lower surface of the first elastic member fixing element 314.

The first bending element 341 may be bent from one side of the first lower fixing element 351 to the inside upwardly.

The second bending element 342 may be bent from one side of the first bending element 341 to the outside upwardly.

The first upper fixing element 352 may be bent from one side of the second bending element 342 to the outside upwardly. In addition, the first upper fixing element 352 may be fixed to an upper surface of the first elastic member fixing element 314.

The first pad connection portion 331 may be bent from one side of the first upper fixing element 352 to the inside thereof.

The other side of the second lower fixing element 353 may be fixed to a lower surface of the second elastic member fixing element 315.

The third bending element 343 may be bent from one side of the second lower fixing element 353 to the inside upwardly.

The fourth bending element 344 may be bent from one side of the third bending element 343 to the outside upwardly.

The second upper fixing element 354 may be bent from one side of the fourth bending element 344 to the outside upwardly. In addition, the second upper fixing element 354 may be fixed to an upper surface of the second elastic member fixing element 315.

The second pad connection element 332 may be bent from one side of the second upper fixing element 354 to the inside thereof. The second pad connection element 332 may be connected with the first pad connection element 331. That is, the first pad connection element 331 and the second pad connection element 332 are connected with each other, and thus, a portion of the first bending element 341 and a portion of the third bending element 343 may be contacted with each other or spaced apart from each other at a predetermined spaced distance. Here, the spaced distance may be smaller than the thickness of the lead terminal 220.

The elastic member 320 is formed of an elastic material, and thus, an elastic force in an upper direction may generate at the first lower fixing element 351 and an elastic force in a lower direction may generate at the first upper fixing element 352. Due to these elastic forces, the first elastic member fixing element 314 may be inserted and fixed between the first lower fixing element 351 and the first upper fixing element 352. In addition, an elastic force in an upper direction may generate at the second lower fixing element 353 and an elastic force in a lower direction may generate at the second upper fixing element 354. Due to these elastic forces, the second elastic member fixing element 315 may be inserted and fixed between the second lower fixing element 353 and the second upper fixing element 354.

As such, the first lower fixing element 351, the second lower fixing element 353, the first upper fixing element 352, the second upper fixing element 354, the first bending element 341, the second bending element 342, the third bending element 343, the fourth bending element 344, the first pad connection element 331, and the second pad connection element 332 may be connected with one another in an integral type, which may constitute the elastic member 320 having a structure shown in FIG. 3.

FIG. 4 is an exemplified view showing an elastic member contacted with a lead terminal and a connection pad according to a preferred embodiment of the present invention.

Referring to FIG. 4, the lead terminal 220 of the semiconductor package 200 may be inserted into the elastic member 320 mounted in the body 310.

For example, the lead terminal 220 may be inserted into the elastic member mounting part 312 from below the body 310. The lead terminal 220 inserted into the elastic member mounting part 312 may be inserted between the first bending element 341 and the third bending element 343 of the elastic member 320. The first bending element 341 and the third bending element 343 may be contacted with each other or spaced apart from each other at a spaced distance smaller than the thickness of the lead terminal 220. Since the first bending element 341 and the third bending element 343 have elastic forces, the lead terminal 220 is inserted therebetween. In addition, the elastic force of the first bending element 341 and the third bending element 343 allow the lead terminal 220 inserted therebetween to be fixed to the elastic member 320.

Also, the elastic member 320 mounted to the body 310 may be contacted with the connection pad 110 of the circuit board 100.

For example, in the case where the circuit board 100 is disposed above the interposer 300, the first pad connection element 331 and the second pad connection element 332 of the elastic member 320 may be contacted with the connection pad 110 of the circuit board 100. Here, the body 310 on which the elastic member 320 is mounted may be formed to have such a thickness that the first pad connection element 331 and the second pad connection element 332 can be contacted with the connection pad 110 of the circuit board 100. Also, the body 310 on which the elastic member 320 is mounted may be formed to have such a height that the first pad connection element 331 and the second pad connection element 332 can be contacted with the connection pad 110 of the circuit board 100.

As such, the elastic member 320 which is contacted with the lead terminal 220 of the semiconductor package 200 and the connection pad 110 of the circuit board 100 may be formed of a conductive material. Therefore, the elastic member 320 is contacted with the lead terminal 220 by allowing the insertion of the lead terminal 220, and contacted with the connection pad 110, and thus, the semiconductor package 200 and the circuit board 100 can be electrically connected with each other.

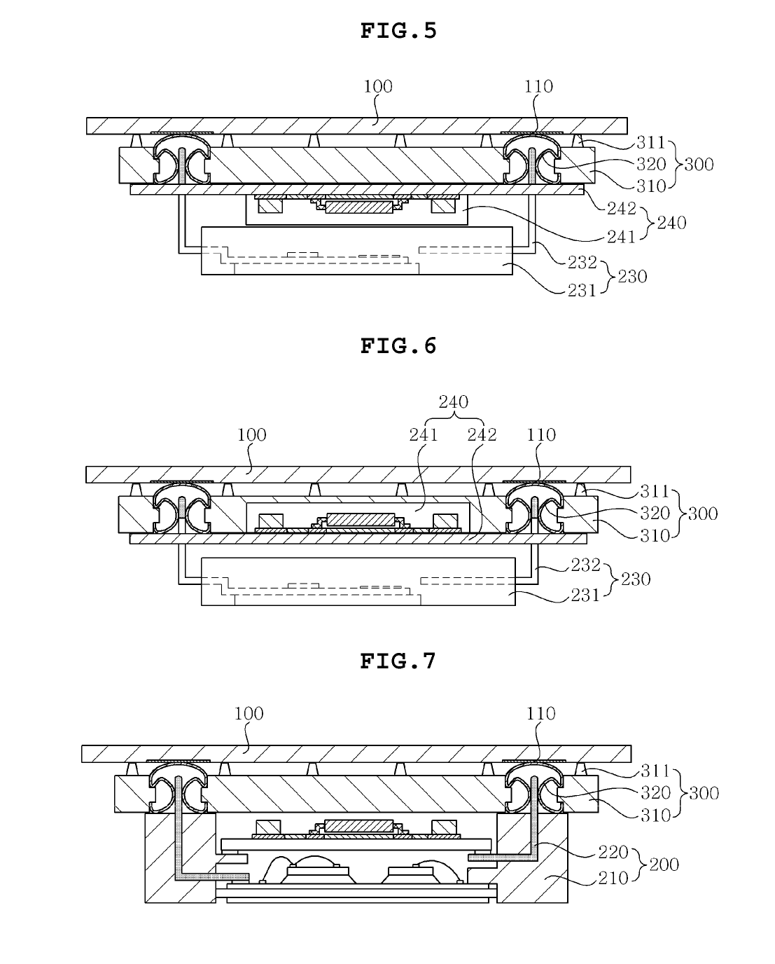

FIG. 5 is an exemplified view showing a semiconductor package module according to another preferred embodiment of the present invention.

Referring to FIG. 5, a semiconductor package module may include a circuit board 100, a first semiconductor package 230, a second semiconductor package 240, and an interposer 300.

The circuit board 100 may be a printed board assembly (PBA) on which a circuit layer is formed or a semiconductor chip is mounted. Connection pads 110 may be formed on one surface of the circuit board 100. The connection pads 110 may be electrically connected with the circuit layer or the semiconductor chip formed on the circuit board 100. The interposer 300 may be formed below the circuit board 100.

The first semiconductor package 230 may include a power device. The first semiconductor package 230 may have a structure where constituents such as the power device, the printed circuit board, and the like are positioned and packaged inside a first housing 210. The first semiconductor package 230 may include lead terminals 232 protruded to the outside of the housing 231. For example, one end of the lead terminal 232 may be electrically connected with the power device or the printed circuit board inside the first housing 231. In addition, the other end of the lead terminal 232 may be protruded to the outside of the first housing 231. The second semiconductor package 240 may be formed above the first semiconductor package 230.

The second semiconductor package 240 may include a control device. The control device may be mounted on a control substrate 242 of the second semiconductor package 240. Here, the control device may be packaged by a second housing 242. The control substrate 242 may be a printed circuit board, and a circuit pattern may be formed thereon. The control substrate 242 may be electrically connected with the control device.

The first semiconductor package 230 and the second semiconductor package 240 may be electrically connected with each other. The lead terminal 232 is penetrated and inserted into, and then electrically connected to the control substrate 242, and thus, the first semiconductor package 230 and the second semiconductor package 240 can be electrically connected with each other. The interposer 300 may be formed above the second semiconductor package 240.

The interposer 300 is a constituent part for electrically connecting the first semiconductor package 230, the second semiconductor package 240, and the circuit board 100 with one another. The interposer 300 may include a body 310 and elastic members 320. The body 310 may be formed of an insulating material. The body 310 may allow the second semiconductor 240 and the circuit board 100 to be spaced apart from each other at a predetermined spaced distance. According to the preferred embodiment of the present invention, protrusions 311 may be formed on the body 310. The protrusions 311 may be formed in order to maintain a spaced distance between the circuit board 100 and the second semiconductor package 240. In the preferred embodiment of the present invention, the drawing shows that the protrusions 311 are formed on only the upper surface 310 of the body 310, but is not limited thereto. The protrusions 311 may be formed on at least one of the upper surface and the lower surface of the body 310.

The elastic members 320 may be mounted inside the body 310. In addition, the elastic members 320 may be formed of a conductive material. The elastic members 320 may be contacted with the lead terminals 232 of the first semiconductor package 230. Also, the elastic members 320 may be contacted with the connection pads 110 of the circuit board 100. The elastic members 320 may be respectively contacted with the lead terminals 232 and the connection pads 110, to thereby electrically connect the lead terminals 232 and the connection pads 110 with each other. That is, the first semiconductor package 230, the second semiconductor package 240, and the circuit board 100 may be electrically connected with one another by the elastic members 320.

FIG. 6 is an exemplified view showing a semiconductor package module according to still another preferred embodiment of the present invention.

Referring to FIG. 6, a semiconductor package module may include a circuit board 100, a first semiconductor package 230, a second semiconductor package 240, and an interposer 300.

The circuit board 100 may be a printed board assembly (PBA) on which a circuit layer is formed or a semiconductor chip is mounted. Connection pads 110 may be formed on one surface of the circuit board 100. The connection pads 110 may be electrically connected with the circuit layer or the semiconductor chip formed on the circuit board 100. The interposer 300 may be formed below the circuit board 100.

The first semiconductor package 230 may include a power device. The first semiconductor package 230 may have a structure where constituents such as the power device, the printed circuit board, and the like are positioned and packaged inside a first housing 210. The first semiconductor package 230 may include lead terminals 232 protruded to the outside of the first housing 231. For example, one end of the lead terminal 232 may be electrically connected with the power device or the printed circuit board inside the first housing 231. In addition, the other end of the lead terminal 232 may be protruded to the outside of the first housing 231. The second package 240 may be formed above the first semiconductor package 230.

The second semiconductor package 240 may include a control device. The control device may be mounted on a control substrate 242 of the second semiconductor package 240, and the control device may be packaged. The control substrate 242 may be a printed circuit board, and a circuit pattern may be formed thereon. The control substrate 242 may be electrically connected with the control device. In the preferred embodiment of the present invention, a portion of the second semiconductor package 240 may be inserted into the body 310 of the interposer 300. For example, the second semiconductor package 240 is inserted and packaged in the body 310 of the interposer 300 while the control device of the second semiconductor package 240 is mounted on the control substrate 242.

The first semiconductor package 230 and the second semiconductor package 240 may be electrically connected with each other. The lead terminal 232 is penetrated and inserted into, and then electrically connected to the control substrate 242, and thus, the first semiconductor package 230 and the second semiconductor package 240 can be electrically connected with each other.

The interposer 300 is one constituent part for electrically connecting the first semiconductor package 230, the second semiconductor package 240, and the circuit board 100 with one another. The interposer 300 may include a body 310 and elastic members 320. The body 310 may be formed of an insulating material. A portion of the second semiconductor package 240 may be inserted into the body 310. In addition, according to the preferred embodiment of the present invention, protrusions 311 may be formed on an upper surface of the body 310. The protrusions 311 may be formed in order to maintain a spaced distance between the circuit board 100 and the second semiconductor package 240.

The elastic members 320 may be mounted inside the body 310. In addition, the elastic members 320 may be formed of a conductive material. The elastic members 320 may be contacted with the lead terminals 232 of the first semiconductor package 230. Also, the elastic members 320 may be contacted with the connection pads 110 of the circuit board 100. The elastic members 320 may be respectively contacted with the lead terminals 232 and the connection pads 110, to thereby electrically connect the lead terminals 232 and the connection pads 110 with each other. That is, the first semiconductor package 230, the second semiconductor package 240, and the circuit board 100 may be electrically connected with one another by the elastic members 320.

FIG. 7 is an exemplified view showing a semiconductor package module according to still another preferred embodiment of the present invention.

Referring to FIG. 7, a semiconductor package module may include a circuit board 100, a semiconductor package 200, and an interposer 300.

The circuit board 100 may be a printed board assembly (PBA) on which a circuit layer is formed or a semiconductor chip is mounted. Connection pads 110 may be formed on one surface of the circuit board 100. The connection pads 110 may be electrically connected with the circuit layer or the semiconductor chip formed on the circuit board 100. The interposer 300 may be formed below the circuit board 100.

The semiconductor package 200 may be a power device or a control device. The semiconductor package 200 may have a structure where constituents such as the power device, the control device, the printed circuit board, and the like are positioned and packaged inside the housing 210. The power device and the control device may be electrically connected with the printed circuit board inside the semiconductor package 200 by wires or a lead frame. According to the preferred embodiment of the present invention, the semiconductor package 200 may be formed in a stacked structure. That is, the power device and the control device, which are internal constituent parts of the semiconductor package 200, may be positioned in a vertically stacked structure. Although the drawing shows that the power device is positioned below the control device, alignment position between the power device and the control device is not limited thereto.

The semiconductor package 200 may include lead terminals 220 protruded to the outside of the housing 210. The lead terminals 220 may electrically connect internal constituent parts and external constituent parts. For example, the internal constituent parts of the semiconductor package 200 may be electrically connected with the circuit board 100 or the elastic member 320 of the interposer 300 through the lead terminals 220. The interposer 300 may be formed above the semiconductor package 200.

The interposer 300 is one constituent part for electrically connecting the semiconductor package 200 and the circuit board 100 with each other. The interposer 300 may include a body 310 and the elastic members 320. The body 310 may be formed of an insulating material. The body 310 may allow the semiconductor package 200 and the circuit board 100 to be spaced apart from each other at a predetermined spaced distance. According to the preferred embodiment of the present invention, protrusions 311 may be formed on the body 310. The protrusions 311 of the body 310 may be also formed in order to maintain the spaced distance between the circuit board 100 and the semiconductor package 200. In the preferred embodiment of the present invention, the drawing shows that the protrusions 311 are formed on only the upper surface of the body 310, but is not limited thereto. The protrusions 311 may be formed on at least one of the upper surface and the lower surface of the body 310.

The elastic members 320 may be mounted inside the body 310. In addition, the elastic members 320 may be formed of a conductive material. The elastic members 320 may be contacted with the lead terminals 220 of the semiconductor package 200. Also, the elastic members 320 may be contacted with the connection pads 110 of the circuit board 100. The elastic members 320 may be respectively contacted with the lead terminals 220 and the connection pads 110, to thereby electrically connect the lead terminals 220 and the connection pads 110 with each other. That is, the semiconductor package 200 and the circuit board 100 may be electrically connected with each other by the elastic members 320.

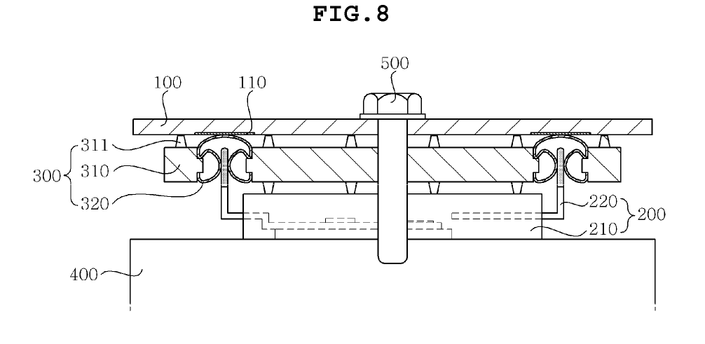

FIG. 8 is an exemplified view showing a semiconductor package module according to still another preferred embodiment of the present invention.

Referring to FIG. 8, a semiconductor package module may include a circuit board 100, a semiconductor package 200, an interposer 300, a heat radiating unit 400, and a coupling unit 500.

The circuit board 100 may be a printed board assembly (PBA) on which a circuit layer is formed or a semiconductor chip is mounted. Connection pads 110 may be formed on one surface of the circuit board 100. The connection pads 110 may be electrically connected with the circuit layer or the semiconductor chip formed on the circuit board 100. The interposer 300 may be formed below the circuit board 100.

The semiconductor package 200 may be a power device or a control device. The semiconductor package 200 may have a structure where constituents such as the power device, the control device, the printed circuit board, and the like are positioned and packaged inside the housing 210. The power device and the control device may be electrically connected with the printed circuit board inside the semiconductor package 200 by wires or a lead frame.

The semiconductor package 200 may include lead terminals 220 protruded to the outside of the housing 210. The lead terminals 220 may electrically connect internal constituent parts and external constituent parts. For example, the internal constituent parts of the semiconductor package 200 may be electrically connected with the circuit board 100 or the elastic member 320 of the interposer 300 through the lead terminals 220. The interposer 300 may be formed above the semiconductor package 200.

The interposer 300 is one constituent part for electrically connecting the semiconductor package 200 and the circuit board 100 with each other. The interposer 300 may include a body 310 and the elastic members 320. The body 310 may be formed of an insulating material. The body 310 may allow the semiconductor package 200 and the circuit board 100 to be spaced apart from each other at a predetermined spaced distance. According to the preferred embodiment of the present invention, protrusions 311 may be formed on an upper surface and a lower surface of the body 310. The protrusions 311 of the body 310 may be also formed in order to maintain the spaced distance between the circuit board 100 and the semiconductor package 200. Although the preferred embodiment of the present invention discloses that the protrusions 311 are formed on the upper surface and the lower surface of the body 310, the protrusion 311 may be omitted.

The elastic members 320 may be mounted inside the body 310. In addition, the elastic members 320 may be formed of a conductive material. The elastic members 320 may be contacted with the lead terminals 220 of the semiconductor package 200. Here, the lead terminals 220 may be inserted into the elastic member 320. The elastic member may be contacted with the lead terminals 220 while fixing the lead terminals 220 inserted by a pressure applied to both lateral surface of the body 310 Also, the elastic members 320 may be contacted with the connection pads 110 of the circuit board 100. The elastic members 320 may be respectively contacted with the lead terminals 220 and the connection pads 110, to thereby electrically connect the lead terminals 220 and the connection pads 110 with each other. That is, the semiconductor package 200 and the circuit board 100 may be electrically connected with each other by the elastic members 320.

The heat radiating unit 400 may be formed below the semiconductor package 200. The heat radiating unit 400 is a constituent part functioning to cool the semiconductor package 200 by radiating the heat generated from the semiconductor package 200 to the outside. For example, the heat radiating unit 400 may be a heat sink or the like.

According to the preferred embodiment of the present invention, the constituent parts constituting the semiconductor package module may be fixed to each other by the coupling unit 500. For example, the coupling unit 500 may be a bolt. As such, as the semiconductor package module is coupled with the coupling unit 500, mutual pressure may be generated above and below the semiconductor package module. That is, the elastic member 320 of the interposer 300 may receive pressure from above and below thereof. The upper surface of the elastic member 320 may be contacted with the connection pads 110 of the circuit board 100 by this pressure.

In the semiconductor package module according to the preferred embodiment o the present invention, the semiconductor package and the circuit board can be electrically connected in a non-soldering manner using the interposer. Further, in the semiconductor package module, the semiconductor package and the circuit board are electrically connected with each other in a non-soldering manner, and thus, generation of cracks due to a difference in coefficient of thermal expansion can be prevented. Further, in the semiconductor package module, the semiconductor package and the circuit board are connected in a structural contact manner, and thus, durability against external physical impact can be improved. Therefore, the semiconductor package module can have improved reliability against thermal or physical stress.

As set forth above, in the semiconductor package module according to the preferred embodiment of the present invention, the semiconductor package and the circuit board are connected with each other in a non-soldering manner, and thus, generation of cracks due to a difference in coefficient of thermal expansion can be prevented.

Further, in the semiconductor package module according to the preferred embodiment of the present invention, the semiconductor package and the circuit board are connected with each other in a non-soldering manner, and thus, damage to the semiconductor package and the circuit board due to heat can be prevented.

Further, in the semiconductor package module according to the preferred embodiment of the present invention, the semiconductor package and the circuit board are connected with each other in a non-soldering manner, and thus, durability against external physical impact can be improved.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A semiconductor package module, comprising:
a circuit board having connection pads formed on one surface thereof;
a semiconductor package including lead terminals protruded out of a housing; and
an interposer positioned between the circuit board and the semiconductor package, the interposer including a body allowing the circuit board and the semiconductor package to be spaced apart from each other and elastic members contacted with the connection pads and the lead terminals.

2. The semiconductor package module as set forth in claim 1, wherein the body includes elastic member mounting parts for mounting the elastic members therein, respectively.

3. The semiconductor package module as set forth in claim 2, wherein the elastic member mounting part is in a penetration hole type penetrating through the body.

4. The semiconductor package module as set forth in claim 2, wherein the elastic member mounting part includes an elastic member fixing portion fixing the elastic member.

5. The semiconductor package module as set forth in claim 4, wherein the elastic member fixing portion includes one pair of first and second elastic member fixing elements protruded from both internal walls of the elastic member mounting part toward a center thereof.

6. The semiconductor package module as set forth in claim 5, wherein the elastic member includes:
a pad connection portion contacted with the connection pads of the circuit board;
a lead insertion portion inserting the lead terminals of the semiconductor package thereinto;
a fixing portion fixed to the elastic member fixing portion of the body.

7. The semiconductor package module as set forth in claim 6, wherein the elastic member is formed in an integral type.

8. The semiconductor package module as set forth in claim 6, wherein the pad connection portion, the lead insertion portion, and the fixing portion of the elastic member are bent toward one another and connected with one another.

9. The semiconductor package module as set forth in claim 8, wherein the elastic member includes:
a first lower fixing element fixed to a lower surface of the first elastic member fixing element formed on one internal wall of the elastic member mounting part;
a first bending element bent from one side of the first lower fixing element to the inside upwardly;
a second bending element bent from one side of the first bending element to the outside downwardly;
a first upper fixing element bent from one side of the second bending element to the outside upwardly, and fixed to an upper surface of the first elastic member fixing element;
a first pad connection element bent from one side of the first upper fixing element to the inside thereof;
a second lower fixing element fixed to a lower surface of the second elastic member fixing element formed on the other internal wall of the elastic member mounting part;
a third bending element bent from one side of the second lower fixing element to the inside upwardly;
a fourth bending element bent from one side of the third bending element to the outside downwardly;
a second upper fixing element bent from one side of the fourth bending element to the outside upwardly, and fixed to an upper surface of the second elastic member fixing element; and
a second pad connection element bent from one side of the second upper fixing element to the inside thereof, one side of the second upper fixing element being connected with one side of the first pad connection element.

10. The semiconductor package module as set forth in claim 9, wherein in the elastic member, the lead terminal of the semiconductor package is inserted and fixed between the second bending element and the fourth bending element.

11. The semiconductor package module as set forth in claim 9, wherein the first pad connection element and the second pad connection element are contacted with the connection pad of the circuit board.

12. The semiconductor package module as set forth in claim 1, wherein the body is formed of an insulating material, and the elastic member is formed of a conductive material.

13. The semiconductor package module as set forth in claim 1, further comprising at least one protrusion protruded from at least one of an upper surface and a lower surface of the body in a thickness direction of the body.

14. The semiconductor package module as set forth in claim 1, wherein the semiconductor package includes at least one of a power device and a control device.

15. The semiconductor package module as set forth in claim 1, wherein the semiconductor package includes:
a first semiconductor package including a power device and the lead terminals protruded out of the housing; and
a second semiconductor package including a control device and a control substrate electrically connected with the lead terminals.

16. The semiconductor package module as set forth in claim 15, wherein the lead terminals are penetration-inserted into the control substrate.

17. The semiconductor package module as set forth in claim 15, wherein the control device is inserted into the body of the interposer.

18. The semiconductor package module as set forth in claim 1, further comprising a heat radiating unit formed below the semiconductor package.

19. The semiconductor package module as set forth in claim 18, wherein the circuit board, the semiconductor package, the interposer, and the heat radiating unit are fixed to one another by a coupling unit.

20. The semiconductor package module as set forth in claim 19, wherein the coupling unit is a bolt.
